(19) United States
(12) Patent Application Publication
(10) Pub. No.: US 2026/0362693 A1
(43) Pub. Date: Nov. 12, 2026

(54) SEMICONDUCTOR DEVICE AND FABRICATION METHODS THEREOF

(71) Applicant: Yangtze Memory Technologies Co., Ltd., Wuhan (CN)

(72) Inventors: Yuhui HAN, Wuhan (CN); Kun ZHANG, Wuhan (CN); Wenxi ZHOU, Wuhan (CN)

(21) Appl. No.: 19/272,766

(22) Filed: Jul. 17, 2025

(30) Foreign Application Priority Data
May 7, 2025 (CN) 202510585514.6

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

Methods, devices, systems, and techniques for managing connecting structures in semiconductor devices are provided. In one aspect, a semiconductor device includes a first stack of first conductive layers and insulating layers alternating with one another along a first direction and a second stack of second conductive layers and insulating layers alternating with one another along the first direction. The semiconductor device also includes a gate line slit structure having a first segment and a second segment between the first stack and the second stack and a connecting structure between the first stack and the second stack along a second direction and between the first segment and the second segment along a third direction, where a first group of conductive layers in the first stack are respectively connected to corresponding conductive layers in the second stack through third conductive layers in the connecting structure.

### CROSS-REFERENCE TO RELATED APPLICATIONS

This application claims priority to Chinese Patent Application No. 202510585514.6, filed on May 7, 2025, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing connecting structures in semiconductor devices.

One aspect of the present disclosure features a semiconductor device. The semiconductor device includes a first stack of first conductive layers and insulating layers alternating with one another along a first direction; a second stack of second conductive layers and insulating layers alternating with one another along the first direction, where the second stack is adjacent to the first stack along a second direction perpendicular to the first direction; a gate line slit structure between the first stack and the second stack along the second direction, where the gate line slit structure includes a first segment and a second segment both extending along a third direction perpendicular to the first direction and the second direction; and a connecting structure between the first stack and the second stack along the second direction and between the first segment and the second segment along the third direction, where a first group of the conductive layers in the first stack are respectively connected to corresponding conductive layers in the second stack through third conductive layers in the connecting structure.

In some implementations, the semiconductor structure further includes a first dielectric structure and a second dielectric structure, where the connecting structure is in contact with and between the first dielectric structure and the second dielectric structure along the first direction.

In some implementations, the first stack further includes a second group of the first conductive layers and a third group of the first conductive layers; the second group of the first conductive layers includes outermost conductive layers in the first stack on a first side of the first stack; the third group of the first conductive layers includes outermost conductive layers in the first stack on a second side of the first stack, where the first side and the second side are opposite along the first direction; the first dielectric structure isolates the second group of the first conductive layers in the first stack from the corresponding second conductive layers in the second stack; and the second dielectric structure isolates the third group of the first conductive layers in the first stack from the corresponding second conductive layers in the second stack.

In some implementations, the first dielectric structure extends beyond the first stack on the first side along the first direction; and the second dielectric structure extends beyond the first stack on the second side along the first direction.

In some implementations, the first dielectric structure, the second dielectric structure, and the connecting structure are between a first dummy channel structure and a second dummy channel structure along the second direction, the first dummy channel structure extends through the first stack along the first direction, and the second dummy channel structure extends through the second stack along the first direction.

In some implementations, the semiconductor device includes a first array region and a connection region adjacent to the first array region along the third direction, the first group of the first conductive layers of the first stack includes at least a fourth conductive layer, the fourth conductive layer includes a first portion in the first array region and a second portion and a third portion both in the connection region, the second portion and the third portion are respectively connected to two opposite ends of the first portion along the second direction, the second portion includes at least a first segment extending along the second direction and a second segment extending along the third direction, and the third portion includes at least a first segment extending along the second direction and a second segment extending along the third direction.

In some implementations, the semiconductor structure further includes contact structures extending along the first direction, where the contact structures are between the second portion of the fourth conductive layer and the third portion of the fourth conductive layer along the second direction, and the contact structures include a first contact structure coupled to the fourth conductive layer.

In some implementations, the first contact structure includes a body extending along the first direction and a base extending along a plane perpendicular to the first direction, and the base is connected to the first segment of the second portion of the fourth conductive layer and the second segment of the third portion of the fourth conductive layer.

In some implementations, the gate line slit structure further includes a third segment extending along the second direction, the second segment and the third segment of the gate line slit structure are in contact with the second portion of the fourth conductive layer, and the second segment and the third segment of the gate line slit structure form a T shape or a cross shape.

In some implementations, the semiconductor device further includes a second array region adjacent to the connection region along the third direction, the connection region is between the first array region and the second array region along the third direction, the contact structures further include a second contact structure and a third contact structure, the second contact structure or the third contact structure is between the first dielectric structure and the first portion of the fourth conductive layer along the third direction.

In some implementations, the second contact structure is coupled to a conductive layer in the second group of the first conductive layers, and the third contact structure is coupled to a conductive layer in the third group of the first conductive layers.

In some implementations, a first size of the first dielectric structure at a first position along the second direction is larger than a second size of the first dielectric structure at a second position along the second direction, and the second position is closer to the connection structure than the first position along the first direction.

Another aspect of the present disclosure features a method of forming a semiconductor device. The method includes forming a first stack of first conductive layers and insulating layers alternating with one another along a first direction and a second stack of second conductive layers and insulating layers alternating with one another along the first direction, where the second stack is adjacent to the first stack along a second direction perpendicular to the first direction; forming a gate line slit structure between the first stack and the second stack along the second direction, where the gate line slit structure includes a first segment and a second segment both extending along a third direction perpendicular to the first direction and the second direction; and forming a connecting structure between the first stack and the second stack along the second direction and between the first segment and the second segment along the third direction, where a first group of the first conductive layers in the first stack are respectively connected to corresponding conductive layers in the second stack through third conductive layers in the connecting structure.

In some implementations, the method further includes forming a first semiconductor structure including a stack of sacrificial layers and insulating layers alternating with one another along the first direction, where the first semiconductor structure includes an array region and a connection region adjacent to the array region along the third direction; and forming gate line holes, channel holes, and dummy channel holes extending through the stack along the first direction, where the gate line holes include a first group of gate line holes, a second group of gate line holes, and a third group of gate line holes, the first group of gate line holes and the second group of gate line holes are arranged along a line extending along the third direction, the third group of gate line holes are arranged along a line extending along the second direction, the channel holes are in the array region, and the dummy channel holes are in the connection region.

In some implementations, the method further includes forming channel structures in the channel holes and dummy channel structures in the dummy channel holes; forming a gate line trench by expanding the gate line holes, where the gate line trench includes a first segment formed by the expanded first group of gate line holes, a second segment formed by the expanded second group of gate line holes, and a third segment formed by the expanded third group of gate line holes, the first segment of the gate line trench and the second segment of the gate line trench are isolated by a portion of the stack; forming conductive layers between the insulating layers of the stack by removing the sacrificial layers of the stack and depositing at least one conductive material into the gate line trench; and removing a conductive material on sidewalls of the gate line trench and forming recesses to isolate the conductive layers of the stack from one another.

In some implementations, forming the gate line slit structure by depositing a dielectric material on the sidewalls of the gate line trench and filling a remaining space of the gate line trench using a semiconductor material, where the first segment of the gate line slit structure is formed in the first segment of the gate line trench, the second segment of the gate line slit structure is formed in the second segment of the gate line trench, and the third segment of the gate line slit structure is formed in the third segment of the gate line trench; forming the first stack and the second stack includes forming the first stack using a first portion of the conductive layers and the insulating layers of the stack on a first side of the gate line slit structure and forming the second stack using a second portion of the conductive layers and the insulating layers of the stack on a second side of the gate line slit structure, where the first side and the second side are opposite along the second direction, and the first stack includes a first group of conductive layers in the middle, a second group of conductive layers on the top, and a third group of conductive layers on the bottom.

In some implementations, the method further includes forming at least a top select gate (TSG) cut in the array region, where the TSG cut includes a dielectric material, extends along the third direction, and extends through the second group of conductive layers of the first stack; and forming at least a first dielectric structure in the connection region, where the first dielectric structure is between the first segment and the second segment of the gate line slit structure along the third direction, extends into the gate line slit structure along the first direction, and extends through the second group of conductive layers of the first stack along the first direction.

In some implementations, the method further includes forming contact structures extending along the first direction in the connection region, where the contact structures include at least a first contact structure coupled to a conductive layer in the first group of conductive layers, a second contact structure coupled to a conductive layer in the second group of conductive layers, a third contact structure coupled to a conductive layer in the second group of conductive layers; forming an interconnect layer on top of the first semiconductor structure; and forming a third semiconductor structure by stacking a second semiconductor structure on top of the interconnect layer and bonding the second semiconductor structure to the interconnect layer, where the third semiconductor structure includes the first semiconductor structure, the interconnect layer, and the second semiconductor structure, and the second semiconductor structure includes a peripheral circuit configured to control the channel structures of the first semiconductor structure.

In some implementations, the method further includes flipping the third semiconductor structure upside down; forming at least a second dielectric structure in the connection region, where the second dielectric structure is between the first segment and the second segment of the gate line slit structure along the third direction, extends into the gate line slit structure along the first direction, and extends through the third group of conductive layers of the first stack along the first direction; and forming the connecting structure includes forming the connecting structure using a remaining portion of conductive layers and insulating layers of the stack between the first dielectric structure and the second dielectric structure along the first direction and between the first segment and the second segment of the gate line slit structure along the third direction.

A further aspect of the present disclosure features a memory system. The memory system includes a memory device and a memory controller coupled to the memory device and configured to control the memory device. The memory device includes a first stack of first conductive layers and insulating layers alternating with one another along a first direction; a second stack of second conductive layers and insulating layers alternating with one another along the first direction, where the second stack is adjacent to the first stack along a second direction perpendicular to the first direction; a gate line slit structure between the first stack and the second stack along the second direction, where the gate line slit structure includes a first segment and a second segment both extending along a third direction perpendicular to the first direction and the second direction; and a connecting structure between the first stack and the second stack along the second direction and between the first segment and the second segment along the third direction, where a first group of the first conductive layers in the first stack are respectively connected to corresponding second conductive layers in the second stack through third conductive layers in the connecting structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1A illustrates a structure overlay view of an example semiconductor device.

FIG. 1B-1D illustrate top views of the example semiconductor devices of FIG. 1A.

FIGS. 1E-1F illustrate cross-sectional views of the example semiconductor device of FIG. 1A.

FIGS. 1G-1H illustrate circuit diagrams of the example semiconductor device of FIG. 1A.

FIGS. 2A-2I show views of structures of a semiconductor device of FIG. 1A at various stages of a fabrication process.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a 3D NAND flash memory) can be formed with a large number of layers and a high aspect ratio. The large number of layers and the high aspect ratio of the memory device may bring challenges to the manufacturing process. For example, the large number of layers can lead to an increase in a total number of string drivers that are coupled to each of the layers of the memory device. Each of the string drivers may take up valuable space in the memory device and is impossible to scale down due to the high voltage application of the string driver. As a result, the string drivers may take up to 20% of a total area of the memory device, reducing the number of memory layers that can be integrated into the memory device. In another example, each of the string drivers is coupled to a corresponding layer of the memory device through a connection structure in a connection region. The number of connection structures also increases corresponding to the larger number of layers, increasing an area of the connection region. Therefore, a contact structure design that can solve the aforementioned issues is desirable.

In one or more implementations of the present disclosure, an example semiconductor device is provided. The semiconductor device includes a first stack of first conductive layers and insulating layers alternating with one another along a first direction; a second stack of second conductive layers and insulating layers alternating with one another along the first direction, where the second stack is adjacent to the first stack along a second direction perpendicular to the first direction; a gate line slit structure between the first stack and the second stack along the second direction, where the gate line slit structure includes a first segment and a second segment both extending along a third direction perpendicular to the first direction and the second direction; and a connecting structure between the first stack and the second stack along the second direction and between the first segment and the second segment along the third direction, where a first group of conductive layers in the first stack are respectively connected to corresponding conductive layers in the second stack through third conductive layers in the connecting structure.

Implementations of the present disclosure can provide one or more of the following technical advantages and/or benefits. First, the connecting structure disclosed in the present disclosure is configured to connect conductive layers in different blocks of the memory device together. The connected conductive layers in different blocks of the memory device can share one string driver. In other words, the connected conductive layers in different blocks of the memory device can reduce the total number of string drivers in the memory device, resulting in a reduction of the area occupied by the string drivers. Second, the connecting structure disclosed in the present disclosure also reduces a number of connecting structures required for the memory device. In other words, the contact structure reduces the area of the connection region. Third, the connecting structure can be easily integrated into the current fabrication process, which simplifies the fabrication process and reduces fabrication costs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

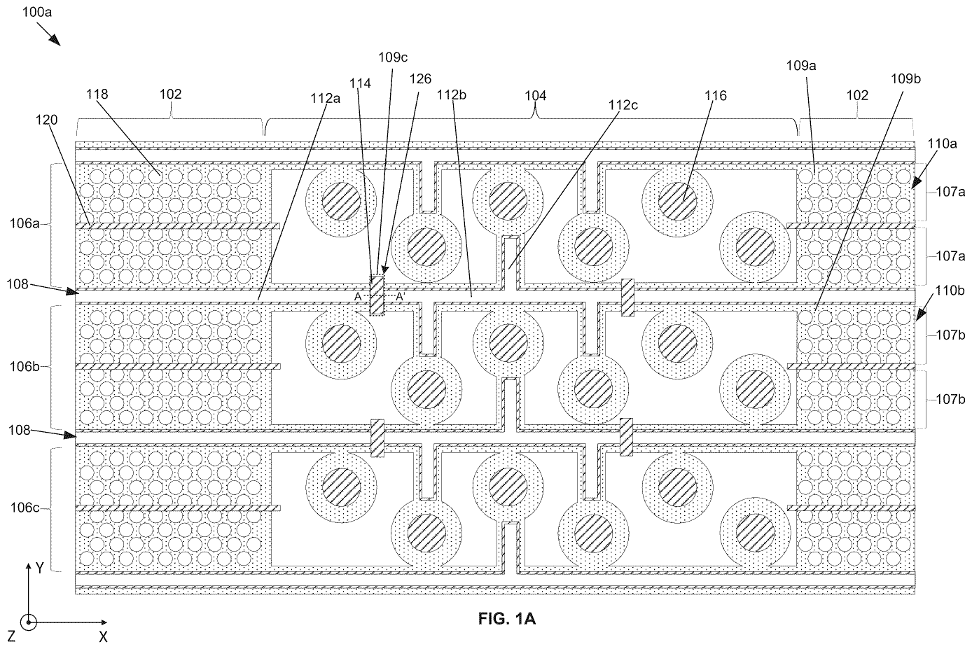

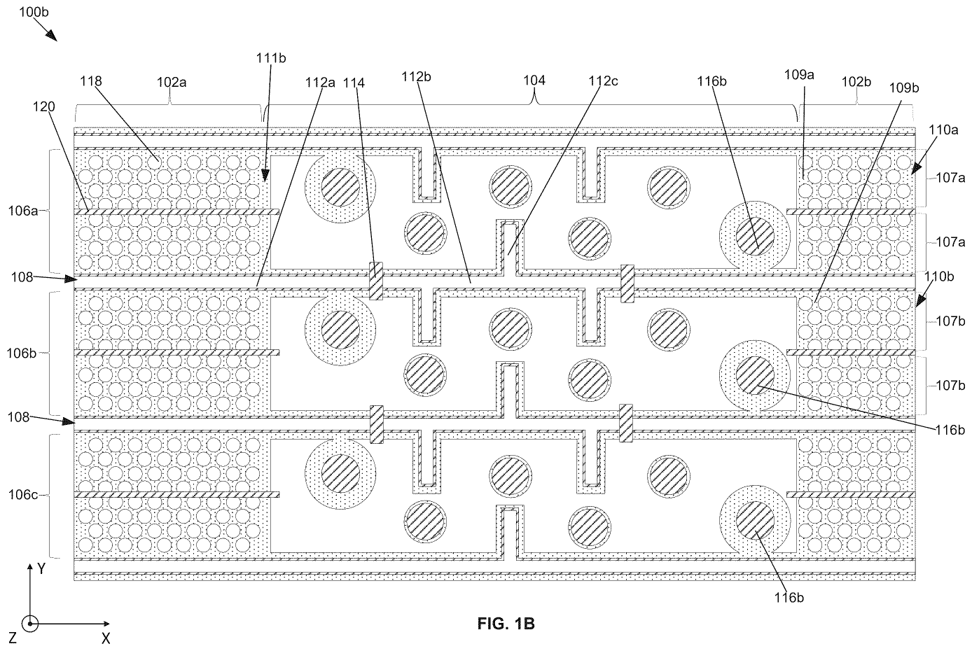

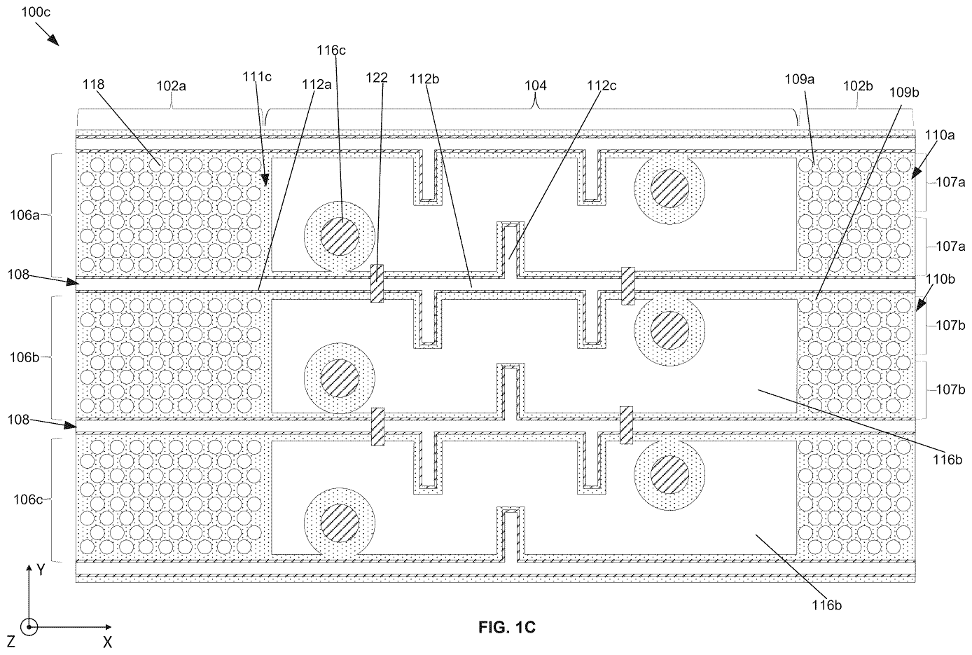

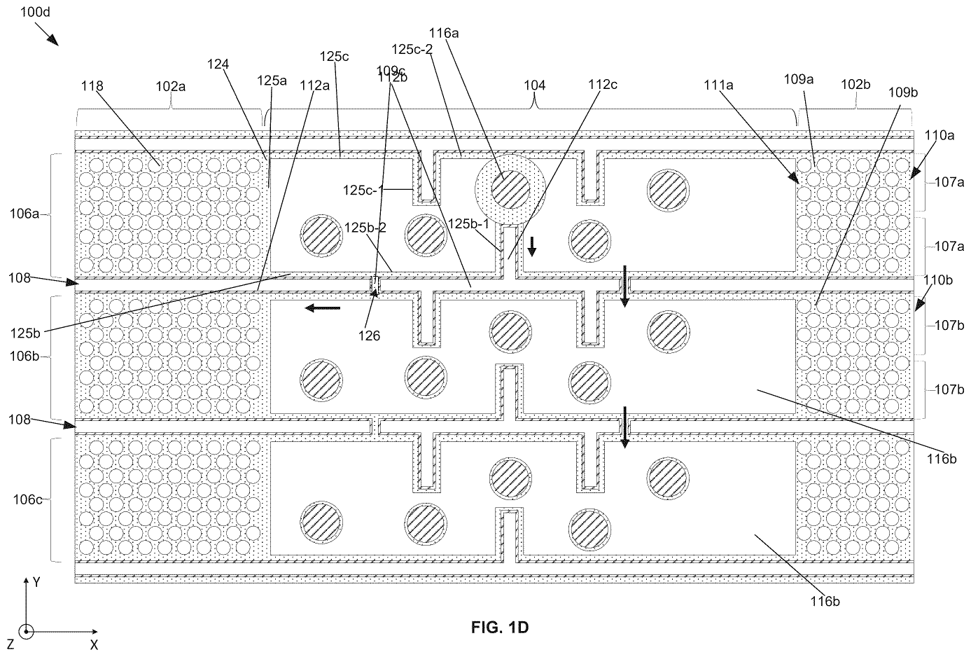

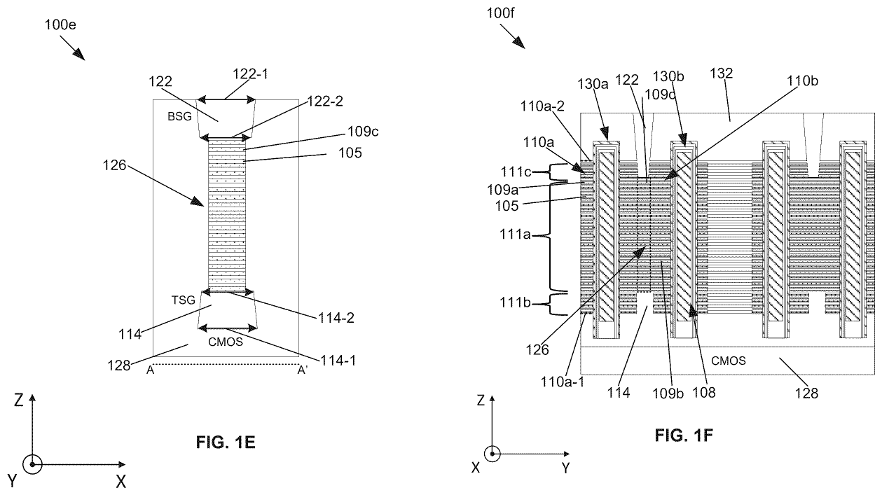

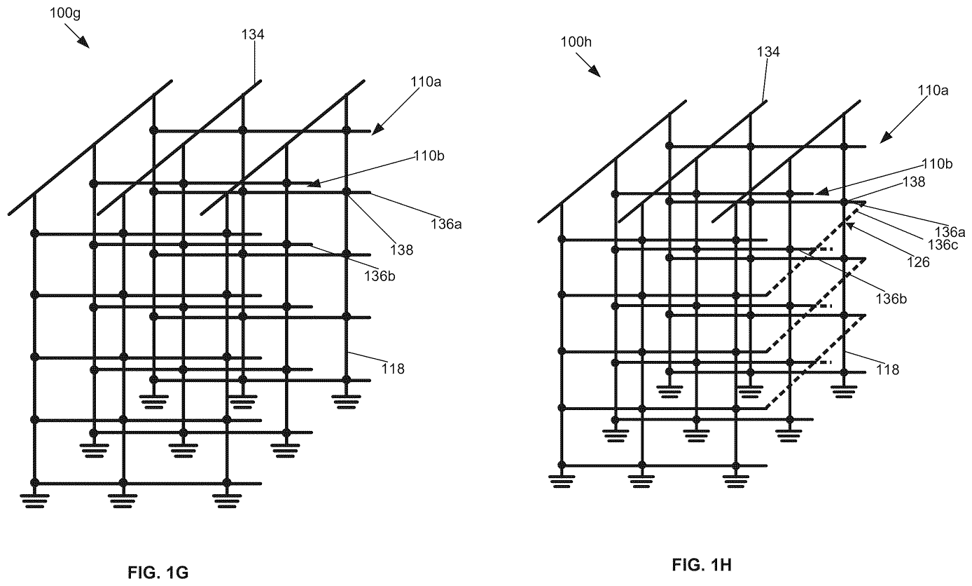

It is noted that X, Y, and Z axes (also referred to as X, Y, and Z directions) are included in FIGS. 1A-1D to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a structure overlay view of an example semiconductor device 100a. The semiconductor device 100a can be a three-dimensional (3D) NAND memory device. As shown in FIG. 1A, the semiconductor device 100a can include one or more array regions 102 and one or more connection regions 104 configured to provide conductive connections for the one or more array regions 102. In some implementations, as shown in FIG. 1A, the semiconductor device 100a includes two array regions 102 and one connection region 104 between the two array regions 102 along a first horizontal direction (e.g., the X direction). It is understood that the example in FIG. 1A is for illustration purpose and is not intended to be construed in a limiting sense. In practice, any suitable arrangement of various regions in the semiconductor device 100a can be applied. In some instances, the semiconductor device 100a can have two connection regions 104 and one array region 102 arranged between the two connection regions 104 along the X direction.

The semiconductor device 100a also includes one or more blocks extending along the X direction. Two adjacent blocks are separated by a gate line slit structure along a second horizontal direction (e.g., the Y direction) perpendicular to the X direction. In some implementations, as shown in FIG. 1A, the semiconductor device 100a includes a first block 106a and a second block 106b that are separated by a gate line slit structure 108.

As shown in FIG. 1A, the first block 106a of the semiconductor device 100a includes a first stack 110a. The first stack 110a includes first conductive layers 109a and insulating layers 105 (as shown in FIG. 1F) alternating with one another along a vertical direction. In some implementations, the vertical direction can be the Z direction that is perpendicular to the X direction and the Y direction. The second block 106b of the semiconductor device 100a includes a second stack 110b. The second stack 110b includes second conductive layers 109b and insulating layers 105 alternating with one another along the Z direction. In some implementations, the first stack 110a is adjacent to the second stack 110b along the Y direction. The first stack 110a and the second stack 110b are separated by the gate line slit structure 108 along the Y direction. In some implementations, each of the insulating layers 105 of the first stack 110a is connected to a corresponding insulating layer 105 of the second stack 110b. For example, each of the insulating layers 105 of the first stack 110a and the corresponding insulating layer 105 of the second stack 110b forms a continuous structure.

In some implementations, the gate line slit structure 108 includes a first segment 112a and a second segment 112b both extending along the X direction. The first segment 112a and the second segment 112b of the gate line slit structure 108 are separated by first dielectric structures 114. In some implementations, as shown in FIG. 1A, the semiconductor device 100a includes two first dielectric structures 114. The two first dielectric structures 114 separate the gate line slit structure 108 into three portions along the X direction, where the second segment 112b is between the first segments 112a along the X direction. In some implementations, the gate line slit structure 108 further includes a third segment 112c extending along the Y direction. In some implementations, as shown in FIG. 1A, the third segment 112c is in contact with the second segment 112b along the Y direction. In some implementations, the second segment 112b and the third segment 112c form a T shape or a cross shape. In some implementations, the two first dielectric structures 114 extend beyond the first stack 110a on a first side of the semiconductor device 100a along the Z direction.

In some implementations, the semiconductor device 100a also includes a connecting structure 126 between the first stack 110a and the second stack 110b along the Y direction. In some implementations, the connecting structure 126 includes third conductive layers 109c and insulating layers 105 alternating with one another along the Z direction. In some implementations, the connecting structure 126 extends along the Z direction and is in contact with a corresponding first dielectric structure 114. In some implementations, a first group 111a of the first conductive layers 109a in the first stack 110a are respectively connected to corresponding second conductive layers 109b in the second stack 110b through the third conductive layers 109c. In some implementations, each of the insulating layers 105 of the first stack 110a is connected to a corresponding insulating layer 105 of the connecting structure 126.

In some implementations, the first stack 110a and the second stack 110b extend into the connection region 104 along the X direction, where the first stack 110a and the second stack 110b are in contact with the gate line slit structure 108. In some implementations, the semiconductor device 100a further includes contact structures 116. The contact structures 116 extend along the Z direction and are between two adjacent gate line slit structures 108 in the connection region 104. In some implementations, the contact structures 116 are coupled to corresponding first conductive layers 109a of the first stack 110a and corresponding second conductive layers 109b of the second stack 110b.

As shown in FIG. 1A, the array regions 102 of the first block 106a and the second block 106b include an array of channel structures 118 extending through the first stack 110a and the second stack 110b. Each of the array of channel structures 118 can be used to form a string of memory cells coupled in serial along the Z direction.

In some implementations, the semiconductor device 100a can include one or more isolation structures 120. The one or more isolation structures 120 extend along the X direction inside the first stack 110a and the second stack 110b. In some implementations, as shown in FIG. 1A, the one or more isolation structures 120 in the first block 106a separates the first block 106a into two or more first fingers 107a. The one or more isolation structures 120 in the second block 106b separates the second block 106b into two or more second fingers 107b. In some implementations, as shown in FIG. 1A, the first fingers 107a are coupled together by a corresponding contact structure 116. The second fingers 107b are coupled together by a corresponding contact structure 116.

In some implementations, as shown in FIG. 1A, the semiconductor device 100a can further include a third block 106c. The third block 106c is separated from the second block 106b by a corresponding gate line slit structure 108 along the Y direction. In some implementations, the second block 106b is between the first block 106a and the third block 106c along the Y direction. In some implementations, the third block 106c has a similar structure compared to the first block 106a and the second block 106b. It is understood that FIG. 1A is for illustration purpose only and a number of blocks in the semiconductor device 100a is not limited to three, where the semiconductor device 100a can include any number of blocks similar to the blocks 106a-106c.

In some implementations, the first conductive layers 109a and the second conductive layers 109b can include a conductive material including, but not limited to, W, Co, Cu, Al, doped silicon, silicides, or any combination thereof. In some implementations, the gate line slit structure 108 can include a conductive material such as poly-Si that is surrounded by a dielectric layer. In some implementations, the gate line slit structure 108 can include a dielectric material such as SiO₂. In some implementations, the contact structures 116 can include a dielectric material surrounded by a conductive material.

FIG. 1B illustrates a top view of an example semiconductor device 100b. The semiconductor device 100b can be a part of the semiconductor device 100a. In some implementations, the first stack 110a includes a second group 111b of the first conductive layers 109a. The second group 111b of the first conductive layers 109a includes outermost first conductive layers 109a from a first side 110a-1 (as shown in FIG. 1F) of the first stack 110a. In some implementations, the semiconductor device 100b includes a conductive layer from the second group 111b of the first conductive layers 109a of the semiconductor device 100a.

As shown in FIG. 1B, the two first dielectric structures 114 isolate the second group 111b of the first conductive layers 109a in the first stack 110a from corresponding second conductive layers 109b in the second stack 110b of the semiconductor device 100b. In some implementations, as shown in FIG. 1B, the semiconductor device 100b includes a first array region 102a and a second array region 102b. The semiconductor device 100b also includes a connection region 104 that is between the first array region 102a and the second array region 102b along the X direction.

The semiconductor device 100b includes a second contact structure 116b. The second contact structure 116b is between one of the two first dielectric structures 114 and either the first array region 102a or the second array region 102b along the X direction. The second contact structure 116b is coupled to a conductive layer in the second group 111b of the first conductive layers 109a. In some implementations, each of the fingers 107a is coupled to a corresponding second contact structure 116b. The second contact structure 116b can be used to select each of the FIG. 107a in the first block 106a during an operation of the semiconductor device 100b. In some implementations, the semiconductor device 100b also includes a second contact structure 116b that is coupled to a second group of the second conductive layers 109b. It is understood FIG. 1B is for illustration purpose only, and the semiconductor device 100b can include any number of blocks that are separated by gate line slit structures 108.

FIG. 1C illustrates a top view of an example semiconductor device 100c. The semiconductor device 100c can be a part of the semiconductor device 100a. In some implementations, the first stack 110a includes a third group 111c of the first conductive layers 109a. The third group 111c of the first conductive layers 109a includes outermost first conductive layers 109a from a second side 110a-2 (as shown in FIG. 1F) of the first stack 110a. The first side 110a-1 and the second side 110a-2 of the first stack 110a are opposite to each other along the Z direction. In some implementations, the semiconductor device 100c includes a conductive layer from the third group 111c of the first conductive layers 109a of the semiconductor device 100a. In some implementations, the semiconductor device 100b and the semiconductor device 100c are at opposite ends of the semiconductor device 100a along the Z direction.

As shown in FIG. 1C, the semiconductor device 100c includes at least one second dielectric structure 122. In some implementations, the connecting structure 126 is between one of the two first dielectric structures 114 (as shown in FIG. 1B) and a corresponding second dielectric structure 122 along the Z direction. In some implementations, the at least one second dielectric structure 122 isolates the third group 111c of the first conductive layers 109a in the first stack 110a from corresponding second conductive layers 109b in the second stack 110b. In some implementations, the at least one second dielectric structure 122 extends beyond the first stack 110a on the second side along the Z direction.

The semiconductor device 100c includes a third contact structure 116c. The third contact structure 116c is between a second dielectric structure 122 and either the first array region 102a or the second array region 102b along the X direction. The third contact structure 116c is coupled to a conductive layer in the third group 111c of the first conductive layers 109a. In some implementations, the semiconductor device 100c can include two third contact structures 116c, where each of the first conductive layers 109a in the third group 111c of the first array region 102a and the first conductive layers 109a in the third group 111c of the second array region 102b is coupled to a corresponding third contact structure 116c. In some implementations, the third contact structure 116c can be used to select an array region 102 during an operation of the semiconductor device 100b. In some implementations, the semiconductor device 100c also includes at least one third contact structure 116c that is coupled to a second group of the second conductive layers 109b. It is understood FIG. 1C is for illustration purpose only, and the semiconductor device 100c can include any number of blocks that are separated by gate line slit structures 108.

FIG. 1D illustrates a top view of an example semiconductor device 100d. The semiconductor device 100d can be a part of the semiconductor device 100a. In some implementations, the semiconductor device 100d includes a conductive layer from the first group 111a of the first conductive layers 109a of the semiconductor device 100a. In some implementations, along the Z direction, the first group 111a of the first conductive layers 109a is between the second group 111b and the third group of the first conductive layers 109a. In some implementations, each of the first conductive layers 109a in the first group 111a is connected to a corresponding third conductive layer 109c of the connecting structure 126. In some implementations, the semiconductor device 100d includes at least a fourth conductive layer 124. The fourth conductive layer 124 can be a conductive layer of the first group 111a of the first conductive layers 109a.

As shown in FIG. 1D, the fourth conductive layer 124 includes a first portion 125a in the first array region 102a, a second portion 125b and a third portion 125c. The second portion 125b and the third portion 125c are both in the connection region 104. The second portion 125b and the third portion 125c are respectively connected to two opposite ends of the first portion 125a along the Y direction. In some implementations, the second portion 125b of the fourth conductive layer 124 includes at least a first segment 125b-1 extending along the Y direction and a second segment 125b-2 extending along the X direction. In some implementations, the third portion 125c of the fourth conductive layer 124 includes at least a first segment 125c-1 extending along the Y direction and a second segment 125c-2 extending along the Y direction.

As shown in FIG. 1D, the contact structures 116 include at least a first contact structure 116a coupled to the fourth conductive layer 124. In some implementations, the first contact structure 116a includes a body extending along the Z direction and a base extending along a plane perpendicular to the Z direction. In some implementations, as shown in FIG. 1D, the base of the first contact structure 116a is connected to the first segment 125b-1 of the second portion 125b and the second segment 125c-2 of the third portion 125c.

In some implementations, as shown in FIG. 1D, the second segment 112b and the third segment 112c of the gate line slit structure 108 are in contact with the second portion 125b. In some implementations, the second segment 112b and the third segment 112c of the gate line slit structure 108 form a T shape or a cross shape.

As shown in FIG. 1D, the semiconductor device 100d includes a connecting structure 126. The third conductive layers 109c of the connecting structure 126 can include a conductive material such as W, Ti, or any other suitable conductive material thereof. In some implementations, the fourth conductive layer 124 of the first group 111a of the first stack 110a is connected to a corresponding second conductive layer 109b of the second stack 110b through the connecting structure. It is understood that FIG. 1D is for illustration purpose only and the semiconductor device 100d can include any number of blocks having a stack of alternating conductive layers and insulating layers, where the fourth conductive layer 124 is coupled to corresponding conductive layers of the blocks through conductive layers in corresponding connecting structures. In some implementations, the first contact structure 116a can be used to select the fourth conductive layer 124 and any conductive layers in any blocks that are coupled to the fourth conductive layer 124 by the conductive layers of the corresponding connecting structures. In some implementations, all of the connected conductive layers in different blocks can share a single string driver, which can reduce a number of string drivers that are needed to control the semiconductor device 100d. Overall footprint of the connection region 104 can also be reduced by using one first contact structure 116a to select all of the connected conductive layers in different blocks.

FIG. 1E illustrates a cross-sectional view of an example semiconductor device 100e along cut line AA′ of FIG. 1A.

The semiconductor device 100e includes one of the two first dielectric structures 114 and a corresponding second dielectric structure 122. In some implementations, the first dielectric structure 114 includes a first end 114-1 and a second end 114-2, and the second dielectric structure 122 includes a first end 122-1 and a second end 122-2. The first end 114-1 and the second end 114-2 of the first dielectric structure 114 are on opposite ends of the first dielectric structure 114 along the Z direction. The first end 112-1 and the second end 112-2 are on opposite ends of the second dielectric structure 122 along the Z direction. In some implementations, a length of the first end 114-1 of the first dielectric structure 114 is greater than a length of the second end 114-2 of the first dielectric structure 114 along the X direction. In some implementations, a length of the first end 122-1 of the second dielectric structure 122 is greater than a length of the second end 122-2 of the second dielectric structure 122 along the X direction. In some implementations, the connecting structure 126 is in contact with and between the first dielectric structure 114 and the second dielectric structure 122 along the Z direction. The connecting structure 126 includes the third conductive layers 109c and the insulating layers 105 alternating with each other along the Z direction. In some implementations, as shown in FIG. 1E, the connecting structure 126 is in contact with the second end 114-2 of the first dielectric structure 114 and the second end 122-2 of the second dielectric structure 122 along the Z direction. In some implementations, the semiconductor device 100e also includes a CMOS layer 128. The CMOS layer can include peripheral circuits that are configured to control the semiconductor device 100e.

FIG. 1F illustrates a cross-sectional view of an example semiconductor device 100f. The semiconductor device 100f can be a cross-sectional view of the semiconductor device 100a cut along the Y axis.

As shown in FIG. 1F, the semiconductor device 100f includes a first dummy channel structure 130a and a second dummy channel structure 130b. The first dummy channel structure 130a extends through the first stack 110a along the Z direction. The second dummy channel structure 130b extends through the second stack 110b along the Z direction. In some implementations, the first dielectric structure 114, the second dielectric structure 122, and the connecting structure 126 are between the first dummy channel structure 130a and the second dummy channel structure 130b along the Y direction. In some implementations, the first dummy channel structure 130a and the second dummy channel structure 130b can be similar to, or same as a channel structure 118 in the array of channel structures 118 of the semiconductor device 100a of FIG. 1A.

As shown in FIG. 1F, the semiconductor device 100f can also include a substrate 132. The substrate 132 can be any suitable semiconductor substrate having any suitable semiconductor material, such as monocrystalline, polycrystalline or single crystalline semiconductor. For example, the substrate 132 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 132 can be removed from the semiconductor device 100f in a later process of manufacturing the semiconductor device 100f. In some implementations, as shown in FIG. 1F, the second dielectric structure 122 extends beyond the first stack 110a and into the substrate 132 along the Z direction. In some implementations, the first dielectric structure 114 extends beyond the first stack 110a and into the CMOS layer 128 along the first direction.

As shown in FIG. 1F, the first stack 110a includes the first group 111a, the second group 111b and the third group 111c of the first conductive layers 109a and the insulating layers 105 alternation with each other along the Z direction. The second group 111b of the first conductive layers 109a of the first stack 110a includes outermost first conductive layers 109a from a first side 110a-1 of the first stack 110a. The third group 111c of the first conductive layers 109a of the first stack 110a includes outermost first conductive layers 109a from a second side 110a-2 of the first stack 110a. The first group 111a is between the second group 111b and the third group 111c along the Z direction. In some implementations, the second group 111b of the first conductive layers 109a are in contact with the first dielectric structure 114 along the Y direction. The third group 111c of the first conductive layers 109a are in contact with the second dielectric structure 122. In some implementations, the first dielectric structure 114 isolates the second group 111b of the first conductive layers 109a from corresponding second conductive layers 109b. The second dielectric structure 122 isolates the third group 111c of the first conductive layers 109a from corresponding second conductive layers 109b. In some implementations, the second stack 110b includes the second conductive layers 109b and the insulating layers 105 alternating with each other along the Z direction. In some implementations, the first dielectric structure 114 extends into the CMOS layer 128 and the second dielectric structure extends into the substrate 132 along the Z direction to ensure an isolation of the second group 111b and the third group 111c of the first conductive layers 109a from the corresponding second conductive layers 109b. In some implementations, the first group 111a of the first conductive layers 109a are respectively connected to corresponding second conductive layers 109b in the second stack 110b through third conductive layers 109c in the connecting structure 126. In some implementations, the first group 111a of the first conductive layers 109a are connected to corresponding second conductive layers 109b. The second group 111b and the third group 111c of the first conductive layers 109a are isolated from the second conductive layers 109b by the first dielectric structure 114 and the second dielectric structure 122.

FIG. 1G illustrates a circuit diagram 100g of the semiconductor device 100a of FIG. 1A. The semiconductor device 100a can be illustrated by the circuit diagram 100g.

As shown in FIG. 1G, the semiconductor device 100a includes one or more bit lines 134. The one or more bit lines 134 are connected with the array of the channel structures 118. In some implementations, as shown in FIG. 1G, first conductive layers 136a of the first stack 110a are separated from second conductive layers 136b of the second stack 110b. In some implementations, the first conductive layers 136a and the second conductive layers 136b can be referred to as word lines. A memory cell 138 is defined by a cross point between the first conductive layers 136a or the second conductive layers 136b and corresponding channel structure 118. In some implementations, each of the first conductive layers 136a and the second conductive layers 136b requires a string driver configured to select a specific memory cell 138.

FIG. 1H illustrates a circuit diagram 100h of the semiconductor device 100a of FIG. 1A. The semiconductor device 100a can be illustrated by the circuit diagram 100h.

As shown in FIG. 1H, a portion of the first conductive layers 136a of the first stack 110a are connected to corresponding second conductive layers 136b of the second stack 110b by the third conductive layers 136c of the connecting structure 126. Memory cells 138 in the connected first conductive layers 136a and second conductive layers 136b can share a single string driver, which reduces a total number of string drivers required to control the semiconductor device 100a as illustrated by the circuit diagram 100h.

In some implementations, the first conductive layers 136a can be same as, or similar to the first conductive layers 109a of FIG. 1A. In some implementations, the second conductive layers 136b can be same as, or similar to the second conductive layers 109b of FIG. 1A. In some implementations, the third conductive layers 136c can be same as, or similar to the third conductive layers 109c of FIG. 1A.

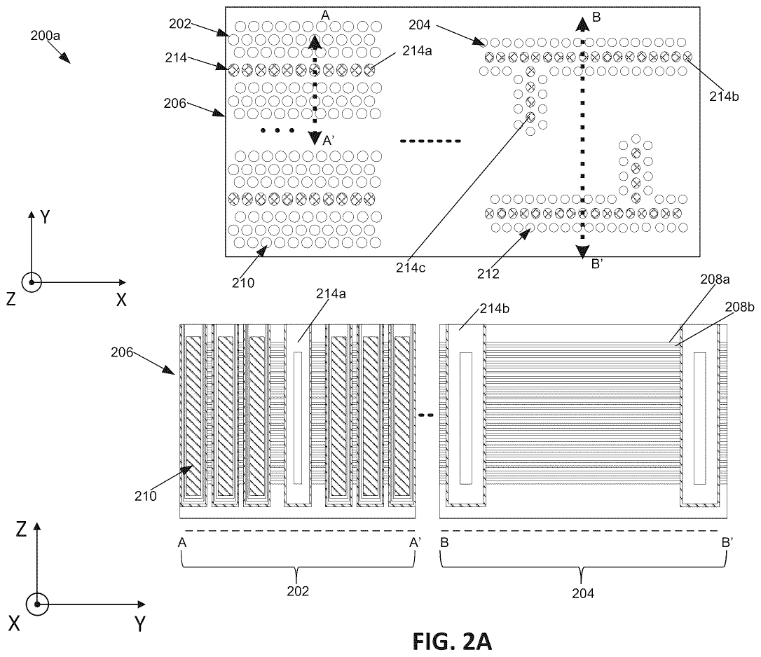

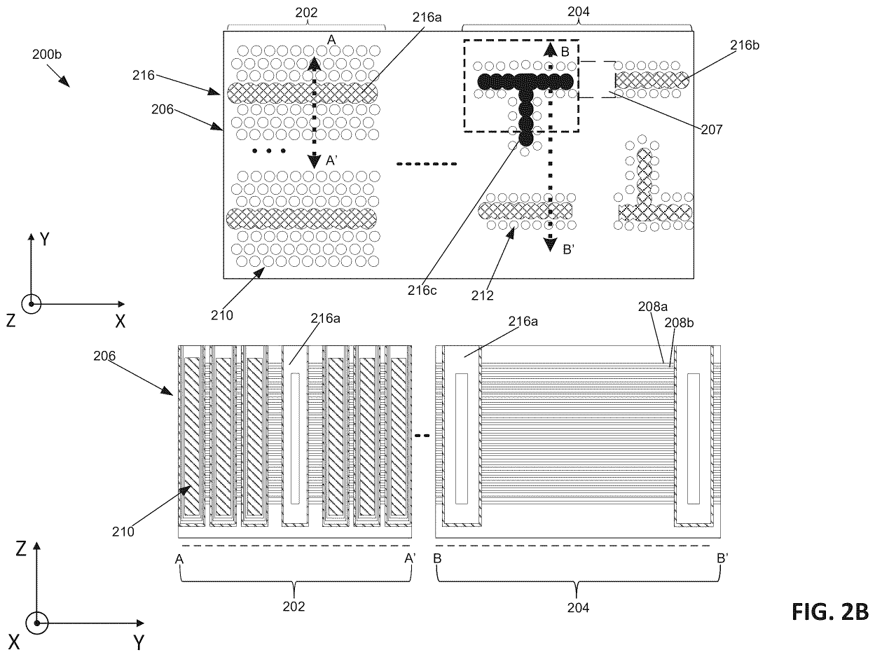

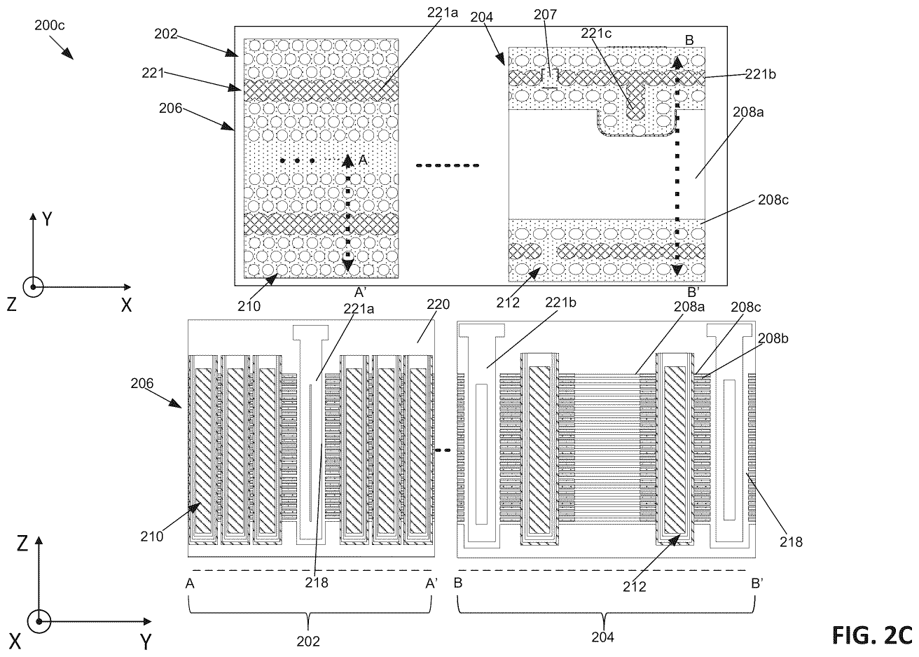

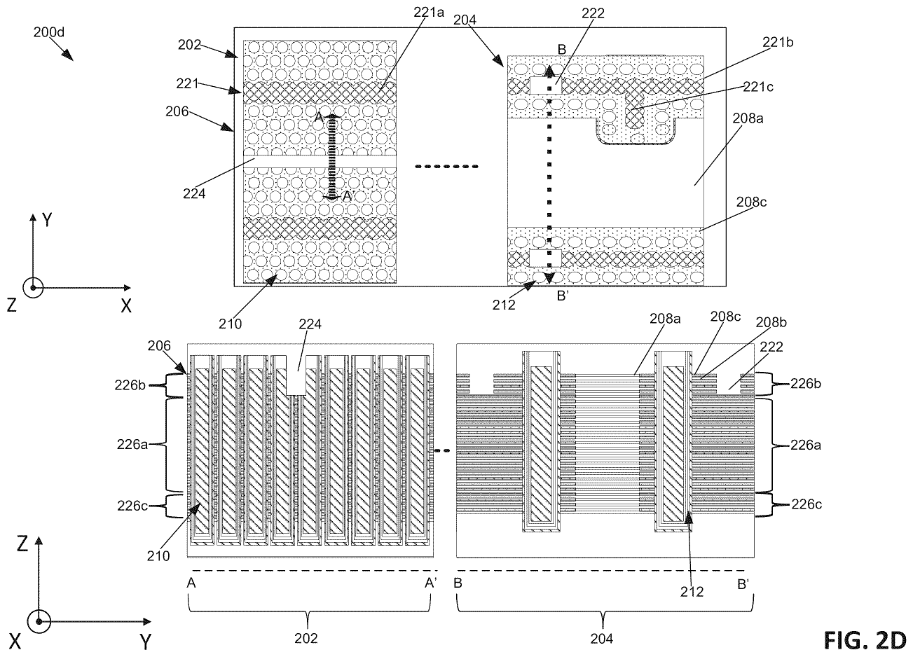

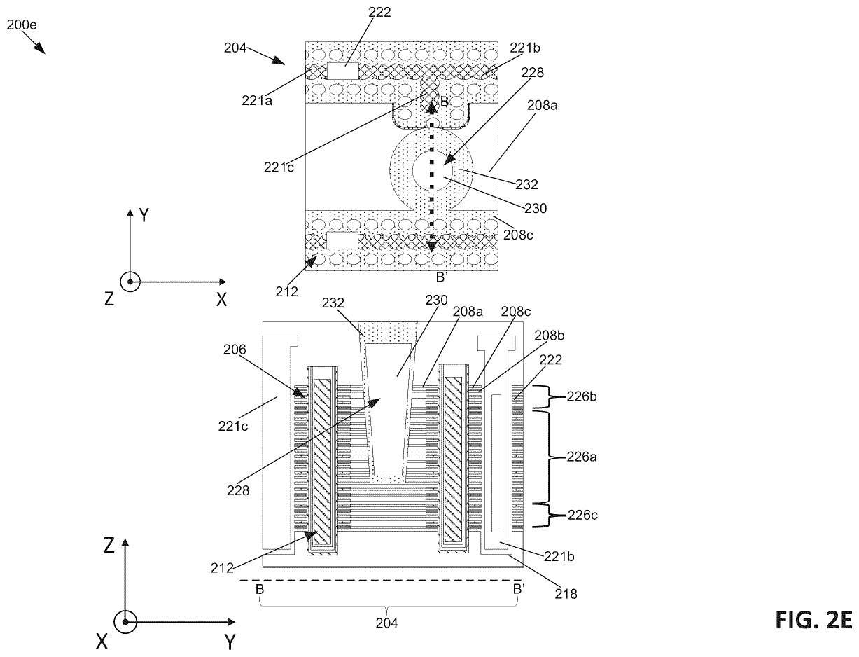

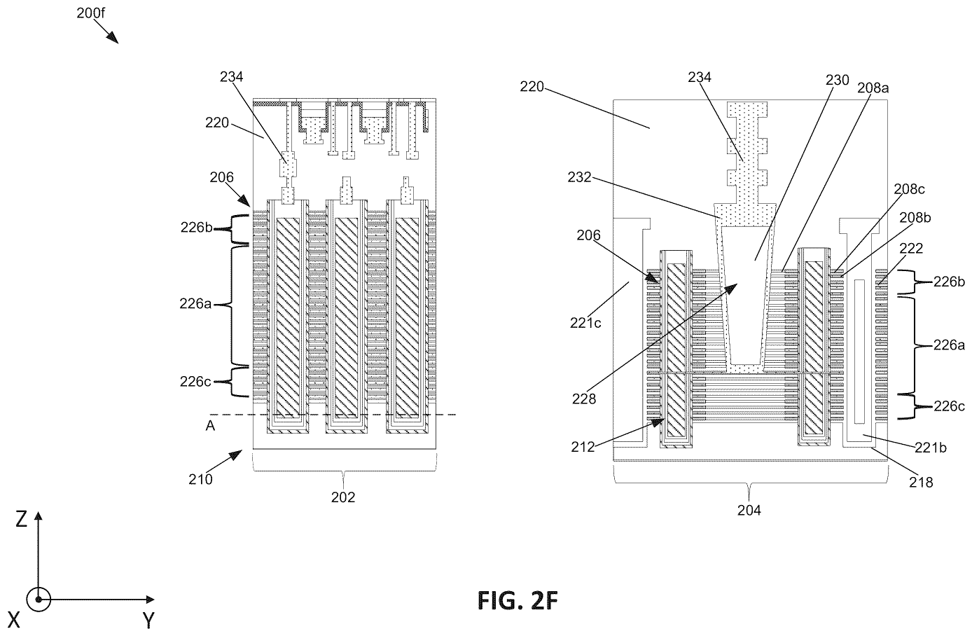

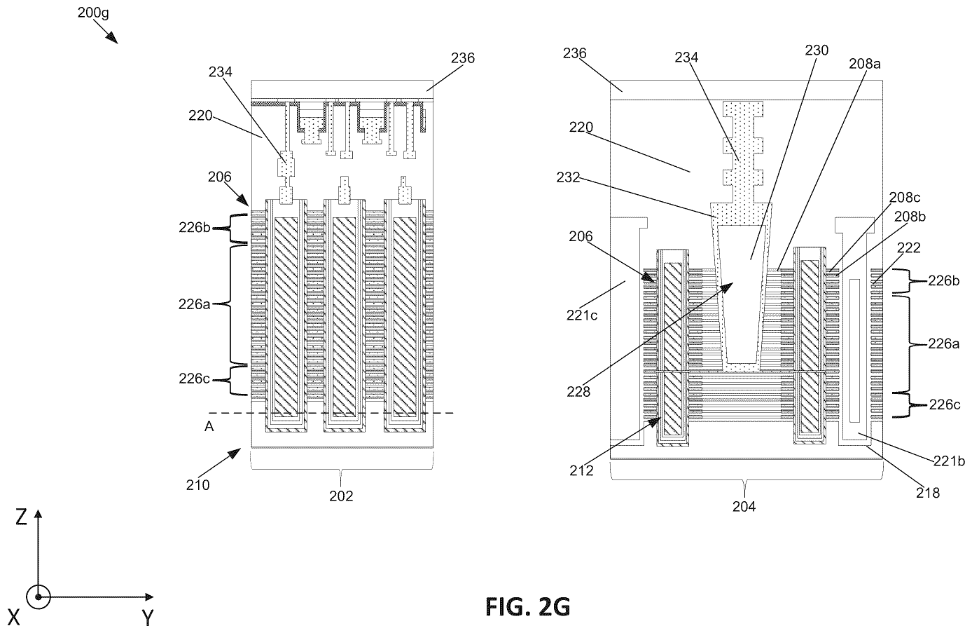

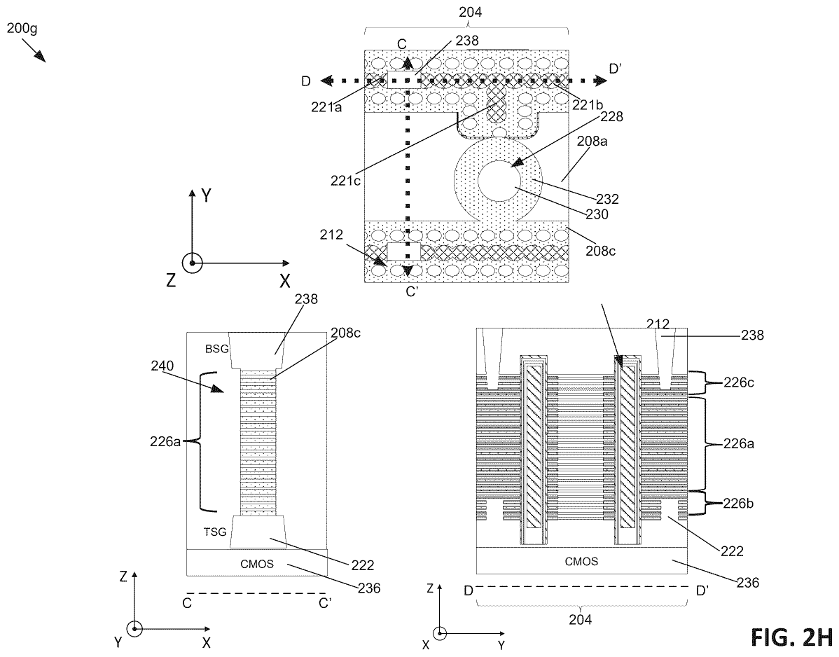

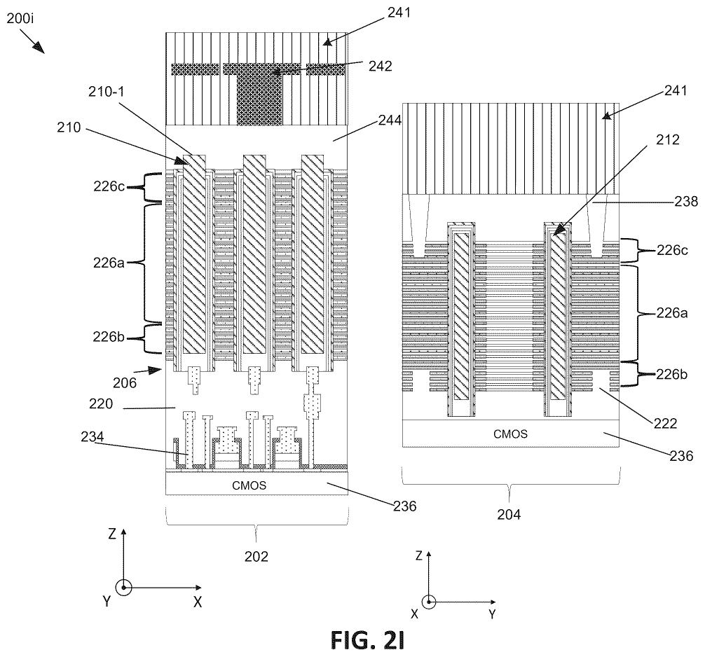

FIGS. 2A-2H illustrate an example process of fabricating a semiconductor device, such as the semiconductor device 100a as illustrated in FIG. 1A. FIGS. 2A-2H show views of example semiconductor structures at various stages of the fabrication process.

FIG. 2A illustrates a semiconductor structure 200a. The semiconductor structure 200a includes an array region 202 and a connection region 204. As shown in FIG. 2A, the semiconductor structure 200a includes a stack 206 of sacrificial layers 208a and insulating layers 208b alternating with one another along a vertical direction (e.g., the Z direction). In some implementations, the array region 202 is adjacent to the connection region 204 along a horizontal direction (e.g., the Y direction) perpendicular to the Z direction. The semiconductor device also includes channel structures 210 in the array region 202 and dummy channel structures 212 in the connection region. In some implementations, the dummy channel structures 212 can be similar to, or same as the channel structures 210. As shown in FIG. 2A, the semiconductor structure 200a also includes gate line holes 214, which can be formed by etching a portion of the stack 206 along the Z direction. The gate line holes 214 are arranged in a first group 214a, a second group 214b, and a third group 214c. The first group 214a of the gate line holes 214 and the second group of the gate line holes 214 are arranged along a line extending along a second horizontal direction (e.g., the X direction) perpendicular to the Y direction and the Z direction. The third group 214c of the gate line holes 214 are arranged along a line extending along the Y direction. In some implementations, as shown in FIG. 2A, the gate line holes 214 can be filled with a sacrificial material such as poly-Si or carbon.

FIG. 2B illustrates a semiconductor structure 200b, which can be formed by expanding the gate line holes 214 to form gate line trench 216. As shown in FIG. 2B, the first group 214a of the gate line holes 214 are connected with each other to form a first segment 216a of the gate line trench 216. The second group 214b of the gate line holes 214 are connected with each other to form a second segment 216b of the gate line trench 216. The third group 214c of the gate line holes 214 are connected with each other to form a third segment 216c of the gate line trench 216. In some implementations, the first segment 216a and the second segment 216b of the gate line trench 216 are isolated by a first portion 207 of the stack 206. In some implementations, the gate line trench 216 can be filled with a sacrificial material such as poly-Si or carbon.

FIG. 2C illustrates a semiconductor structure 200c, which can be formed by replacing a portion of sacrificial material in the sacrificial layers 208a of the stack 206 with at least one conductive material to form conductive layers 208c. The conductive material of the conductive layers 208c can be formed by depositing the at least one conductive material from the gate line trench 216. As shown in FIG. 2C, the conductive layers 208c of the stack 206 are isolated from each other, which can be achieved by removing the at least one conductive material on sidewalls of the gate line trench 216 to form a recess to isolate the conductive layers 208c from one another. In some implementations, the semiconductor structure 200c also includes a dielectric layer 220, which can be formed by depositing a dielectric material on top of the stack 206. The semiconductor structure 200c also includes a gate line slit structure 221. The gate line slit structure 221 can be formed by depositing a dielectric material on the sidewalls of the gate line trench 216 to form a dielectric layer 218 and filling a remaining space of the gate line trench 216 with a semiconductor material. A first segment 221a of the gate line slit structure 221 is formed in the first segment 216a of the gate line trench 216, a second segment 221b of the gate line slit structure 221 is formed in the second segment 216b of the gate line trench 216, and third segment 221c of the gate line slit structure 221 is formed in the third segment 216c of the gate line trench 216. In some implementations, the gate line trench 216 can be filled with a sacrificial material such as poly-Si or carbon. In some implementations, the gate line trench 216 extends into the dielectric layer 220 along the Z direction.

As shown in FIG. 2D, a semiconductor structure 200d is formed. The semiconductor structure 200d includes at least one top select gate (TSG) cut 224 in the array region 202 and at least one first dielectric structure 222 in the connection region 204. The at least one first dielectric structure 222 can be formed by etching at least one conductive layer 208c from the first portion 207 of the stack 206 along the Z direction and filling the etched portion with a dielectric material (e.g., SiO₂). The at least one TSG cut 224 can be formed by etching at least one conductive layer 208c of the stack 206 in the array region 202 along the Z direction and filling the etched portion with a dielectric material. As shown in FIG. 2D, the conductive layers 208c of the stack 206 include a first group 226a, the conductive layers 208c in middle, a second group 226b of the conductive layers 208c on top, and a third group 226c of the conductive layers 208c on bottom. As shown in FIG. 2D, the TSG cut 224 is in contact with the second group 226b of the conductive layers 208c in the array region 202 and the at least one first dielectric structure 222 is in contact with the second group 226b of the conductive layers 208c in the connection region 204.

As shown in FIG. 2E, a semiconductor structure 200e is formed. The semiconductor structure 200e includes a contact structure 228. The contact structure includes a dielectric body 230 surrounded by a conductive layer 232. The contact structure 228 can be formed by etching a remaining portion of the sacrificial layers 208a and the insulating layers 208b of the stack 206 in the connection region 204 and filling the etched portion with a dielectric material surrounded by a conductive material.

FIG. 2F illustrates a semiconductor structure 200f, which can be formed by forming an interconnect layer 234 in the dielectric layer 220. As shown in FIG. 2F, the interconnect layer 234 is coupled to the channel structures 210 in the array region 202 and the conductive layer 232 of the contact structure 228 in the connection region 204.

FIG. 2G illustrates a semiconductor structure 200g, which can be formed by bonding a CMOS die 236 on top of the dielectric layer 220. In some implementations, the CMOS die 236 includes peripheral circuits. The peripheral circuits of the CMOS die are coupled to the interconnect layer 234 and configured to control the contact structure 228 and the channel structures 210.

FIG. 2H illustrates different views of the semiconductor structure 200g. As shown in FIG. 2H, the semiconductor structure 200g further includes at least one second dielectric structure 238. The second dielectric structure 238 can be formed by etching a portion of the third group 226c of the conductive layers 208c in the connection region 204 from a bottom of the semiconductor structure 200g and filling the etched portion with a dielectric material. The bottom of the semiconductor structure 200g is on an opposite side of the CMOS die 236 along the Z direction. A connecting structure 240 can be defined by the first group 226a of the conductive layers 208c between the first dielectric structure 222 and the second dielectric structure 238.

FIG. 2I illustrates a semiconductor structure 200i which can be formed by depositing a dielectric material on the bottom of the semiconductor structure 200g to form a device layer 241. In some implementations, the bottom of the semiconductor structure 200g is opposite to the CMOS die 236 along the Z direction. As shown in FIG. 2I, the semiconductor structure 200i also includes interconnect layers 242 in the array region 202. The interconnect structure 242 can be formed inside the device layer 241 with a conductive material. In some implementations, the interconnect structure 242 is coupled to first ends 210-1 of the channel structures 210. The first ends 210-1 of the channel structures are closer to the device layer 241 than the CMOS die 236 along the Z direction. In some implementations, as shown in FIG. 2I, the first ends 210-10 of the channel structures 210 are connected together by a semiconductor layer 244. In some implementations, the semiconductor layer 244 is referred to as an array common source 242 for the channel structures 210. In some implementations, the interconnect structure 242 is coupled to the channel structures 210 through the array common source 242. In some implementations, the array common source 242 is connected to the interconnect structure 242 along the Z direction.

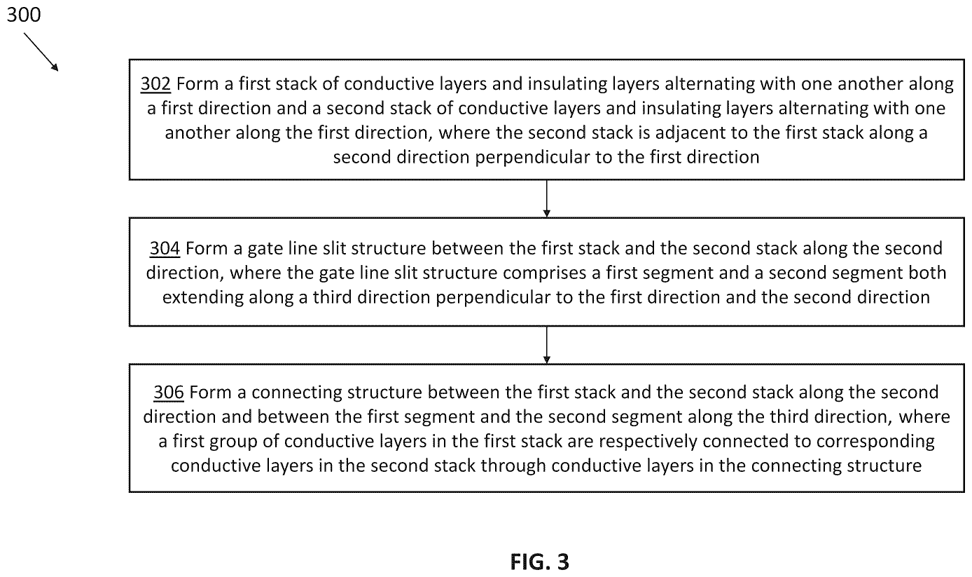

FIG. 3 illustrates a flow chart of an example process 300. The process 300 can be performed to form a semiconductor device (e.g., the semiconductor device 100a illustrated by FIG. 1A). The process 300 can be described in view of FIGS. 2A-2H. The process 300 can include one or more steps of the fabrication process of forming the semiconductor structures in FIGS. 2A-2H. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a first stack (e.g., the first stack 110a of FIG. 1A) of conductive layers and insulating layers alternating with one another along a first direction (e.g., the Z direction) and a second stack (e.g., the second stack 110b of FIG. 2A) of conductive layers and insulating layers alternating with one another along the first direction is formed, wherein the second stack is adjacent to the first stack along a second direction (e.g., the Y direction) perpendicular to the first direction.

At operation 304, a gate line slit structure (e.g., the gate line slit structure 221 of FIG. 2C) between the first stack and the second stack along the second direction is formed, wherein the gate line slit structure comprises a first segment (e.g., the first segment 221a of FIG. 2C) and a second segment (e.g., the second segment 221b of FIG. 2C) both extending along a third direction perpendicular to the first direction and the second direction.

At operation 306, a connecting structure (e.g., the connecting structure 240 of FIG. 2H) between the first stack and the second stack along the second direction and between the first segment and the second segment along the third direction is formed, wherein a first group (e.g., the first group 226a of FIG. 2D) of conductive layers in the first stack are respectively connected to corresponding conductive layers in the second stack through conductive layers in the connecting.

In some implementations, the method further includes forming a first semiconductor structure including a stack (e.g., the stack 206) of sacrificial layers (e.g., the sacrificial layers 208a of FIG. 2A) and insulating layers (e.g., the insulating layers 208b of FIG. 2A) alternating with one another along the first direction, where the first semiconductor structure includes an array region (e.g., the array region 202 of FIG. 2A) and a connection region (e.g. the connection region 204 of FIG. 2A) adjacent to the array region along the third direction; and forming gate line holes (e.g., the gate line holes 214 of FIG. 2A), channel holes, and dummy channel holes extending through the stack along the first direction, where the gate line holes include a first group (e.g., the first group 214a of FIG. 2A) of gate line holes, a second group (e.g., the second group 214b of FIG. 2A) of gate line holes, and a third group (e.g., the third group 214c of FIG. 2A) of gate line holes, the first group of gate line holes and the second group of gate line holes are arranged along a line extending along the third direction, the third group of gate line holes are arranged along a line extending along the second direction, the channel holes are in the array region, and the dummy channel holes are in the connection region.

In some implementations, the method further includes forming channel structures (e.g., the channel structures 210 of FIG. 2A) in the channel holes and dummy channel structures (e.g., the dummy channel structures 212 of FIG. 2A) in the dummy channel holes; forming a gate line trench (e.g., the gate line trench 216 of FIG. 2B) by expanding the gate line holes, where the gate line trench includes a first segment (e.g., the first segment 216a of FIG. 2B) formed by the expanded first group of gate line holes, a second segment (e.g., the second segment 216b of FIG. 2B) formed by the expanded second group of gate line holes, and a third segment (e.g., the third segment 216c of FIG. 2B) formed by the expanded third group of gate line holes, the first segment of the gate line trench and the second segment of the gate line trench are isolated by a portion (e.g., the first portion 207 of FIG. 2B) of the stack; forming conductive layers (e.g., the conductive layers 208c of FIG. 2C) between the insulating layers of the stack by removing the sacrificial layers of the stack and depositing at least one conductive material into the gate line trench; and removing a conductive material on sidewalls of the gate line trench and forming recesses to isolate the conductive layers of the stack from one another.

In some implementations, forming the gate line slit structure by depositing a dielectric material on the sidewalls of the gate line trench and filling a remaining space of the gate line trench using a semiconductor material, where the first segment of the gate line slit structure is formed in the first segment of the gate line trench, the second segment of the gate line slit structure is formed in the second segment of the gate line trench, and the third segment of the gate line slit structure is formed in the third segment of the gate line trench; forming the first stack and the second stack includes forming the first stack using a first portion of the conductive layers and the insulating layers of the stack on a first side of the gate line slit structure and forming the second stack using a second portion of the conductive layers and the insulating layers of the stack on a second side of the gate line slit structure, where the first side and the second side are opposite along the second direction, and the first stack includes a first group (e.g., the first group 226a of FIG. 2D) of conductive layers in the middle, a second group (e.g., the second group 226b of FIG. 2D) of conductive layers on the top, and a third group (e.g., the third group 226c of FIG. 2D) of conductive layers on the bottom.

In some implementations, the method further includes forming at least a top select gate (TSG) cut (e.g., the TSG cut 224 of FIG. 2D) in the array region, where the TSG cut includes a dielectric material, extends along the third direction, and extends through the second group of conductive layers of the first stack; and forming at least a first dielectric structure (e.g., the first dielectric structure 222 of FIG. 2D) in the connection region, where the first dielectric structure is between the first segment and the second segment of the gate line slit structure along the third direction, extends into the gate line slit structure along the first direction, and extends through the second group of conductive layers of the first stack along the first direction.

In some implementations, the method further includes forming contact structures (e.g., the contact structure 228 of FIG. 2E) extending along the first direction in the connection region, where the contact structures include at least a first contact structure (e.g., the first contact structure 116a of FIG. 1D) coupled to a conductive layer in the first group of conductive layers, a second contact structure (e.g., the second contact structure 116b of FIG. 1B) coupled to a conductive layer in the second group of conductive layers, a third contact structure (e.g., the third contact structure 116c of FIG. 1C) coupled to a conductive layer in the second group of conductive layers; forming an interconnect layer (e.g., the interconnect layer 234 of FIG. 2F) on top of the first semiconductor structure; and forming a third semiconductor structure (e.g., the semiconductor structure 200g of FIG. 2G) by stacking a second semiconductor structure (e.g., the CMOS die 236 of FIG. 2G) on top of the interconnect layer and bonding the second semiconductor structure to the interconnect layer, where the third semiconductor structure includes the first semiconductor structure, the interconnect layer, and the second semiconductor structure, and the second semiconductor structure includes a peripheral circuit configured to control the channel structures of the first semiconductor structure.

In some implementations, the method further includes flipping the third semiconductor structure upside down; forming at least a second dielectric structure (e.g., the second dielectric structure 238 of FIG. 2H) in the connection region, where the second dielectric structure is between the first segment and the second segment of the gate line slit structure along the third direction, extends into the gate line slit structure along the first direction, and extends through the third group of conductive layers of the first stack along the first direction; and forming the connecting structure includes forming the connecting structure using a remaining portion of conductive layers and insulating layers of the stack between the first dielectric structure and the second dielectric structure along the first direction and between the first segment and the second segment of the gate line slit structure along the third direction.

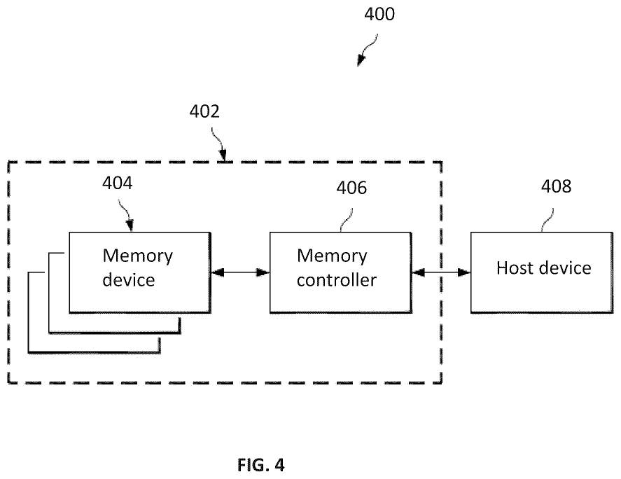

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed in the present disclosure, such as a memory device (e.g., a NAND Flash memory) as shown in FIGS. 1A-1D. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What the claim is:

1. A semiconductor device, comprising:
a first stack of first conductive layers and insulating layers alternating with one another along a first direction;
a second stack of second conductive layers and insulating layers alternating with one another along the first direction, wherein the second stack is adjacent to the first stack along a second direction perpendicular to the first direction;
a gate line slit structure between the first stack and the second stack along the second direction, wherein the gate line slit structure comprises a first segment and a second segment both extending along a third direction perpendicular to the first direction and the second direction; and
a connecting structure between the first stack and the second stack along the second direction and between the first segment and the second segment along the third direction, wherein a first group of the conductive layers in the first stack are respectively connected to corresponding conductive layers in the second stack through third conductive layers in the connecting structure.

2. The semiconductor device of claim 1, further comprising a first dielectric structure and a second dielectric structure, wherein the connecting structure is in contact with and between the first dielectric structure and the second dielectric structure along the first direction.

3. The semiconductor device of claim 2, wherein:
the first stack further comprises a second group of the first conductive layers and a third group of the first conductive layers;
the second group of the first conductive layers comprises outermost conductive layers in the first stack on a first side of the first stack;
the third group of the first conductive layers comprises outermost conductive layers in the first stack on a second side of the first stack, wherein the first side and the second side are opposite along the first direction;
the first dielectric structure isolates the second group of the first conductive layers in the first stack from the corresponding second conductive layers in the second stack; and
the second dielectric structure isolates the third group of the first conductive layers in the first stack from the corresponding second conductive layers in the second stack.

4. The semiconductor device of claim 3, wherein:
the first dielectric structure extends beyond the first stack on the first side along the first direction; and
the second dielectric structure extends beyond the first stack on the second side along the first direction.

5. The semiconductor device of claim 3, wherein the first dielectric structure, the second dielectric structure, and the connecting structure are between a first dummy channel structure and a second dummy channel structure along the second direction, the first dummy channel structure extends through the first stack along the first direction, and the second dummy channel structure extends through the second stack along the first direction.

6. The semiconductor device of claim 3, wherein the semiconductor device comprises a first array region and a connection region adjacent to the first array region along the third direction, the first group of the first conductive layers of the first stack comprises at least a fourth conductive layer, the fourth conductive layer comprises a first portion in the first array region and a second portion and a third portion both in the connection region, the second portion and the third portion are respectively connected to two opposite ends of the first portion along the second direction, the second portion comprises at least a first segment extending along the second direction and a second segment extending along the third direction, and the third portion comprises at least a first segment extending along the second direction and a second segment extending along the third direction.

7. The semiconductor device of claim 6, further comprising contact structures extending along the first direction, wherein the contact structures are between the second portion of the fourth conductive layer and the third portion of the fourth conductive layer along the second direction, and the contact structures comprise a first contact structure coupled to the fourth conductive layer.

8. The semiconductor device of claim 7, wherein the first contact structure comprises a body extending along the first direction and a base extending along a plane perpendicular to the first direction, and the base is connected to the first segment of the second portion of the fourth conductive layer and the second segment of the third portion of the fourth conductive layer.

9. The semiconductor device of claim 6, wherein the gate line slit structure further comprises a third segment extending along the second direction, the second segment and the third segment of the gate line slit structure are in contact with the second portion of the fourth conductive layer, and the second segment and the third segment of the gate line slit structure form a T shape or a cross shape.

10. The semiconductor device of claim 7, further comprises a second array region adjacent to the connection region along the third direction, the connection region is between the first array region and the second array region along the third direction, the contact structures further comprise a second contact structure and a third contact structure, the second contact structure or the third contact structure is between the first dielectric structure and the first portion of the fourth conductive layer along the third direction.

11. The semiconductor device of claim 10, wherein the second contact structure is coupled to a conductive layer in the second group of the first conductive layers, and the third contact structure is coupled to a conductive layer in the third group of the first conductive layers.

12. The semiconductor device of claim 3, wherein a first size of the first dielectric structure at a first position along the second direction is larger than a second size of the first dielectric structure at a second position along the second direction, and the second position is closer to the connection structure than the first position along the first direction.

13. A method comprising:
forming a first stack of first conductive layers and insulating layers alternating with one another along a first direction and a second stack of second conductive layers and insulating layers alternating with one another along the first direction, wherein the second stack is adjacent to the first stack along a second direction perpendicular to the first direction;
forming a gate line slit structure between the first stack and the second stack along the second direction, wherein the gate line slit structure comprises a first segment and a second segment both extending along a third direction perpendicular to the first direction and the second direction; and
forming a connecting structure between the first stack and the second stack along the second direction and between the first segment and the second segment along the third direction, wherein a first group of the first conductive layers in the first stack are respectively connected to corresponding conductive layers in the second stack through third conductive layers in the connecting structure.

14. The method of claim 13, further comprising:
forming a first semiconductor structure comprising a stack of sacrificial layers and insulating layers alternating with one another along the first direction, wherein the first semiconductor structure comprises an array region and a connection region adjacent to the array region along the third direction; and
forming gate line holes, channel holes, and dummy channel holes extending through the stack along the first direction, wherein the gate line holes comprise a first group of gate line holes, a second group of gate line holes, and a third group of gate line holes, the first group of gate line holes and the second group of gate line holes are arranged along a line extending along the third direction, the third group of gate line holes are arranged along a line extending along the second direction, the channel holes are in the array region, and the dummy channel holes are in the connection region.

15. The method of claim 14, further comprising:
forming channel structures in the channel holes and dummy channel structures in the dummy channel holes;
forming a gate line trench by expanding the gate line holes comprising the first group of gate line holes, the second group of gate line holes, and the third group of gate line holes, wherein the gate line trench comprises a first segment formed by the expanded first group of gate line holes, a second segment formed by the expanded second group of gate line holes, and a third segment formed by the expanded third group of gate line holes, the first segment of the gate line trench and the second segment of the gate line trench are isolated by a portion of the stack;
forming conductive layers between the insulating layers of the stack by removing the sacrificial layers of the stack and depositing at least one conductive material into the gate line trench; and
removing a conductive material on sidewalls of the gate line trench and forming recesses to isolate the conductive layers of the stack from one another.

16. The method of claim 15, wherein:
forming the gate line slit structure by depositing a dielectric material on the sidewalls of the gate line trench and filling a remaining space of the gate line trench using a semiconductor material, wherein the first segment of the gate line slit structure is formed in the first segment of the gate line trench, the second segment of the gate line slit structure is formed in the second segment of the gate line trench, and the third segment of the gate line slit structure is formed in the third segment of the gate line trench;
forming the first stack and the second stack comprises forming the first stack using a first portion of the conductive layers and the insulating layers of the stack on a first side of the gate line slit structure and forming the second stack using a second portion of the conductive layers and the insulating layers of the stack on a second side of the gate line slit structure, wherein the first side and the second side are opposite along the second direction, and the first stack comprises a first group of conductive layers in the middle, a second group of conductive layers on top, and a third group of conductive layers on bottom.

17. The method of claim 16, further comprising:
forming at least a top select gate (TSG) cut in the array region, wherein the TSG cut comprises a dielectric material, extends along the third direction, and extends through the second group of conductive layers of the first stack; and
forming at least a first dielectric structure in the connection region, wherein the first dielectric structure is between the first segment and the second segment of the gate line slit structure along the third direction, extends into the gate line slit structure along the first direction, and extends through the second group of conductive layers of the first stack along the first direction.

18. The method of claim 17, further comprising:
forming contact structures extending along the first direction in the connection region, wherein the contact structures comprise at least a first contact structure coupled to a conductive layer in the first group of conductive layers, a second contact structure coupled to a conductive layer in the second group of conductive layers, a third contact structure coupled to a conductive layer in the second group of conductive layers;
forming an interconnect layer on top of the first semiconductor structure; and
forming a third semiconductor structure by stacking a second semiconductor structure on top of the interconnect layer and bonding the second semiconductor structure to the interconnect layer, wherein the third semiconductor structure comprises the first semiconductor structure, the interconnect layer, and the second semiconductor structure, and the second semiconductor structure comprises a peripheral circuit configured to control the channel structures of the first semiconductor structure.

19. The method of claim 18, further comprising:
flipping the third semiconductor structure upside down;
forming at least a second dielectric structure in the connection region, wherein the second dielectric structure is between the first segment and the second segment of the gate line slit structure along the third direction, extends into the gate line slit structure along the first direction, and extends through the third group of conductive layers of the first stack along the first direction; and
forming the connecting structure comprises forming the connecting structure using a remaining portion of conductive layers and insulating layers of the stack between the first dielectric structure and the second dielectric structure along the first direction and between the first segment and the second segment of the gate line slit structure along the third direction.

20. A memory system, comprising:
a memory device; and
a memory controller coupled to the memory device and configured to control the memory device,
wherein the memory device comprises:
a first stack of first conductive layers and insulating layers alternating with one another along a first direction;
a second stack of second conductive layers and insulating layers alternating with one another along the first direction, wherein the second stack is adjacent to the first stack along a second direction perpendicular to the first direction;
a gate line slit structure between the first stack and the second stack along the second direction, wherein the gate line slit structure comprises a first segment and a second segment both extending along a third direction perpendicular to the first direction and the second direction; and
a connecting structure between the first stack and the second stack along the second direction and between the first segment and the second segment along the third direction, wherein a first group of the first conductive layers in the first stack are respectively connected to corresponding second conductive layers in the second stack through third conductive layers in the connecting structure.
